(19) United States
(12) Patent Application Publication
(10) Pub. No.: US 2025/0069579 A1
(43) Pub. Date: Feb. 27, 2025

(54) FAN NOISE REDUCTION

(71) Applicants: Advanced Micro Devices, Inc., Santa Clara, CA (US); XILINX, INC., San Jose, CA (US)

(72) Inventors: Gamal REFAI-AHMED, Santa Clara, CA (US); Christopher JAGGERS, Austin, TX (US); Hoa DO, San Jose, CA (US); Md Malekkul ISLAM, Santa Clara, CA (US); Paul Theodore ARTMAN, Cary, NC (US); Sukesh SHENOY, Austin, TX (US); Suresh RAMALINGAM, Fremont, CA (US); Muhammad Afiq Bin In BAHAROM, Butterworth (MY)

(21) Appl. No.: 18/236,221

(22) Filed: Aug. 21, 2023

(51) Int. Cl. G10K 11/178

(52) U.S. Cl. CPC G10K 11/17825; G10K 11/17881; G10K 11/17883; H05K 7/20136; H05K 7/20209

(57) ABSTRACT

In one example, a micro device includes a housing; a chip package disposed in the housing; a noise producing component coupled to the housing. The micro device also includes a noise reduction system having a reference microphone for detecting a noise from the noise producing component and a controller configured to receive the noise from the reference microphone and generate a masking sound signal in response to the detected noise. A speaker is coupled to the housing for producing a masking sound corresponding to the masking sound signal, whereby the masking sound reduces the noise. In another example, the noise producing component comprises a fan.

### TECHNICAL FIELD

Embodiments of the present invention generally relate to fan noise reduction in a micro device.

### BACKGROUND

Micro devices, such as electronic devices, photonic devices, microelectromechanical systems (MEMS) and/or RF devices, often employ electronic components which leverage chip package assemblies for increased functionality and higher component density. Conventional chip packaging schemes often utilize a package substrate, often in conjunction with a through-silicon-via (TSV) interposer, to enable a plurality of integrated circuit (IC) dies to be mounted to a single package substrate. The IC dies may include memory, logic or other IC devices. These micro devices containing one or more chip packages are frequently utilized in advanced electronic computing systems, such as found in telecomm and datacomm equipment, cellular antennas, data centers and automotive electronics, among others.

In many chip package assemblies, providing adequate thermal management has become increasingly challenging. Failure to provide adequate cooling often results in diminished service life and even device failure. Thermal management is particularly desirable in applications where active components have high current and power usage, and correspondingly generate high heat loads.

Cooling fans have been used as a thermal management device in micro devices. Cooling fans transfer heat using forced convection. An undesirable effect of cooling fans is the generation of noise during operation. Fan noise typically increase with an increase in fan speed. As such, staying within fan noise requirements often result in limitations on the fan speed. In turn, the amount of cooling output of the cooling fan is also limited.

Often, these micro devices may encounter a system event that requires the attention of the operator. For example, system events such as extreme fan noise, device failures, or overheat events due to inadequate thermal management should be relayed to the operator. Some devices include a warning light to draw attention to these system events. However, the warning light may be visible to the operator only from certain locations or distances.

There is, therefore, a need for an audio apparatus for reducing noise from a cooling fan of a micro device. There is also a need for audio apparatus that can generate a verbal warning message to warn an operator of system events.

### SUMMARY

In one example, a micro device includes a housing; a chip package disposed in the housing; a noise producing component coupled to the housing. The micro device also includes a noise reduction system having a reference microphone for detecting a noise from the noise producing component and a controller configured to receive the noise from the reference microphone and generate a masking sound signal in response to the detected noise. A speaker is coupled to the housing for producing a masking sound corresponding to the masking sound signal, whereby the masking sound reduces the noise. In another example, the noise producing component comprises a fan.

In another example, an electronic device includes a housing, a chip package disposed in the housing, and a plurality of fans coupled to the housing. A fan controller controls a fan noise by controlling a rotational position of a blade of a first fan of the plurality of fans relative to a rotational position of a blade of a second fan of the plurality of fans.

In another example, an electronic system includes a housing, a printed circuit board disposed in the housing, and a chip package connected to the printed circuit board. The electronic system also includes an audio system having a controller configured to receive a warning signal and to generate a verbal warning message which communicates at least one of a location or a nature of a warning corresponding to the warning signal and a speaker for producing the verbal warning message.

In another example, a micro device includes a housing; a chip package disposed in the housing; and a fan coupled to the housing. The micro device also includes a noise reduction system having a reference microphone for detecting a noise produced by the fan. A controller receives the noise from the reference microphone and generate a masking sound signal in response to the detected noise. A speaker attached to the fan produces a masking sound corresponding to the masking sound signal, whereby the masking sound reduces the noise.

In another example, a method of operating a micro device includes operating a fan to transfer heat away from the micro device. The method also includes detecting a noise produced by the fan using a reference microphone. A masking sound signal is generated in response to the detected noise. A speaker attached to the fan produces a masking sound corresponding to the masking sound signal, thereby reducing the noise from the fan.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic view of a micro device having a chip package and a noise reduction system, according to some embodiments.

FIG. 2 illustrates an exemplary embodiment of the chip package of FIG. 1.

FIG. 3 is a diagram of an exemplary noise reduction system suitable for use with the micro device of FIG. 1.

FIG. 4 is a front view of a fan of the micro device of FIG. 1.

FIG. 5 is a flow diagram of a method of reducing noise from a micro device, according to some embodiments.

FIG. 6 is a diagram of a noise reduction system having a plurality of fans operating at the same clock rate, according to some embodiments.

FIG. 7 is a diagram of an exemplary audio system suitable for use with the micro device of FIG. 1.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A micro device includes a chip package, a fan, and a noise reduction system. The noise reduction system can detect a noise produced by the fan and, in response, can generate a masking sound to reduce the detected noise. In some embodiments, the noise reduction system includes a reference microphone for detecting the noise, a controller for analyzing the noise and generating a masking sound signal, and a speaker for producing the masking sound. In some embodiments, the noise reduction system may additionally produce an anti-noise to at least partially cancel the noise. The reduced fan noise allows the fan to increase its output, thereby increasing its effectiveness in dissipating heat. In some embodiments, an audio system can generate a verbal warning message to communicate at least one of a location or a nature of a system event requiring attention.

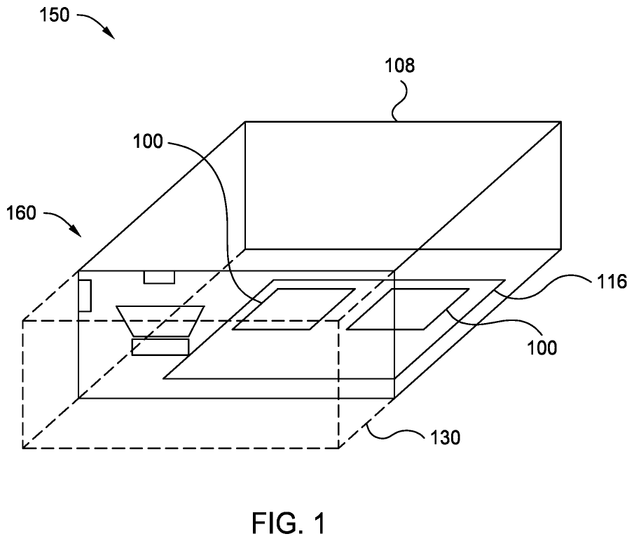

Turning now to FIG. 1, a schematic view of a micro device 150 having a housing 108 and two chip packages 100 disposed therein, according to some embodiments. The chip packages 100 are mounted to a printed circuit board (PCB) 116. The micro device 150 additionally includes a cooling fan 130 attached to the PCB 116 and a noise reduction system 160. The cooling fan 130 function to transfer heat away from the chip packages 100.

In FIG. 1, the micro device 150 includes two chip packages 100 mounted to the printed circuit board 116. Although two chip packages 100 are shown, one, three, four, or more chip packages 100 may be mounted to the printed circuit board 116. Each of the chip packages 100 may be configured as a silicon device, a MEMS device, a photonic device, an RF device, or combinations thereof.

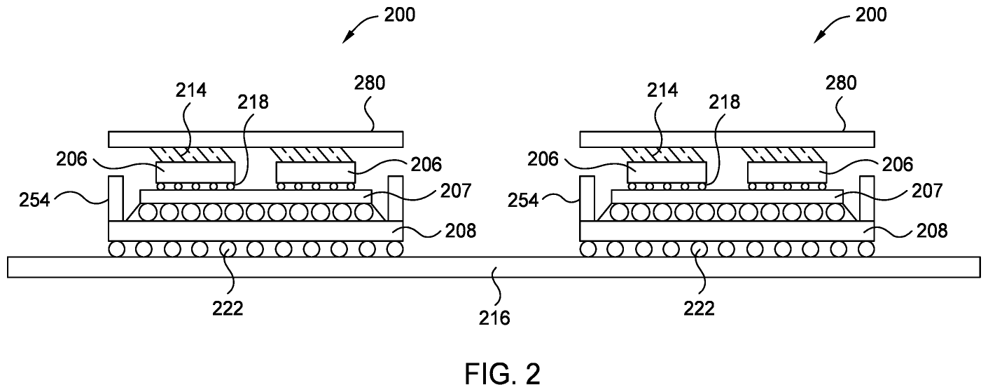

FIG. 2 illustrates an exemplary embodiment of chip packages 200 suitable for use as the chip packages 100 of the micro device 150 shown in FIG. 1. Each chip package 200 includes one or more integrated circuit (IC) dies 206 and a package substrate 208. In this example, two integrated circuit dies 206 are electrically and mechanically mounted to the package substrate 208. Optionally, the integrated circuit dies 206 may be electrically and mechanically mounted to an interposer 207, with the interposer 207 electrically and mechanically mounted to the package substrate 208. The package substrate 208 of the chip package 200 is mounted to the PCB 216 to form at least a portion of the micro device, such as micro device 150. In some embodiments, each chip package 200 may have the same or different number of IC dies 206. Each chip package may include any suitable number of IC dies 206 that may fit on the PCB 216, such as three, six, or nine IC dies. Examples of IC dies 206 that may be utilized in the chip package 200 include, but are not limited to, logic and memory devices, such as field programmable gate arrays (FPGA), application-specific integrated circuits (ASICs), memory devices, such as high band-width memory (HBM), optical devices, processors or other IC logic or memory structures. One or more of the IC dies 206 may optionally include optical devices such as photo-detectors, lasers, optical sources, and the like.

Functional circuitry of the IC dies 206 is connected to the circuitry of the package substrate 208 through the solder connections 218 or other suitable electrical connection, such as a hybrid connecter comprised of metal circuit connection material disposed in a dielectric sheet. A bottom surface of the package substrate 208 is electrically and mechanically coupled to the circuitry of the PCB 216 via solder connections 222 when the chip package 200 is mounted to an upper surface of the PCB 216 to form the micro device, such as micro device 150.

A stiffener 254 may be coupled to the package substrate 208 and circumscribe the IC dies 206. The stiffener 254 can extend to peripheral edges of the package substrate 208 to provide mechanical support, which helps prevent the chip package 200 from bowing and warpage. The stiffener 254 may be a single-layer structure or a multi-layer structure. The stiffener 254 may be made of ceramic, metal, or other various inorganic materials, such as aluminum oxide (Al₂O₃), aluminum nitride (AlN), silicon nitride (SiN), silicon (Si), copper (Cu), aluminum (Al), diamond, and stainless steel, among other materials. The stiffener 254 can also be made of organic materials such as copper-clad laminate.

A lid 280 may be disposed over the IC dies 206. In some examples, the lid 280 may be fabricated from a thermally conductive material, such as copper, nickel-plated copper, or aluminum, among other suitable materials. In this respect, the lid 280 functions as a thermal management device, such as thermal management device 102. Additional thermal management devices, either active or passive, may optionally be mounted to the top surface of the lid 280. In some embodiments, a thermal interface material (TIM) 214 may be utilized to thermally and/or mechanically couple the lid 280 to the IC dies 206.

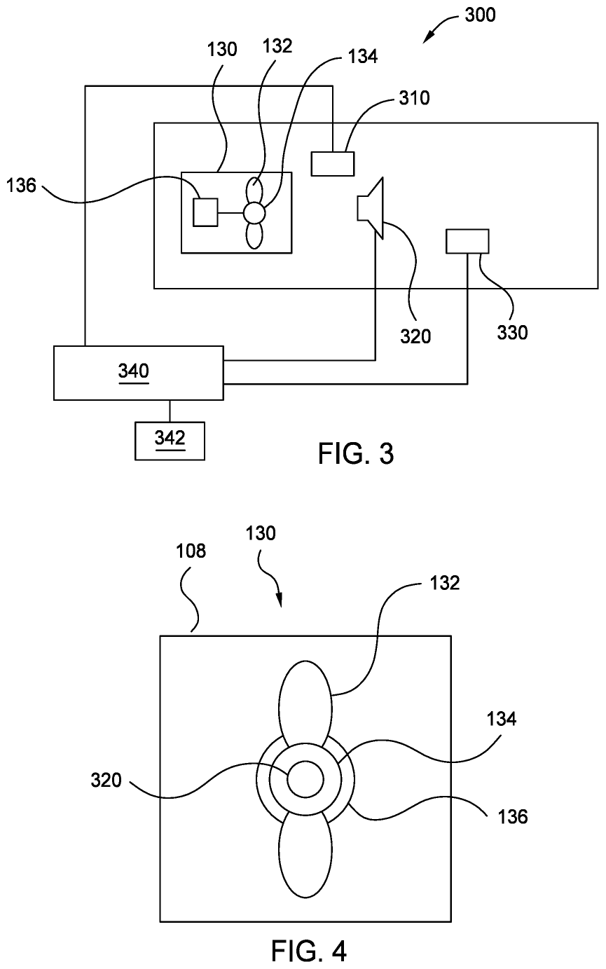

The micro device 150 includes a cooling fan 130 as a thermal management device to remove heat from the chip packages 100. In one example, the cooling fan 130 has a plurality of blades 132, as shown in FIG. 3 and FIG. 4. FIG. 3 is a schematic view of the fan 130, and FIG. 4 is a front view of the fan 130. The blades 132 are attached to a hub 134 and are arranged circumferentially around the hub 134. A motor 136 is connected to the hub 134 for rotating the hub 134, and thereby rotating the blades 132. During rotation, air flows through the blades 132 from an inlet side of the fan 130 to an outlet side of the fan 130. With reference to FIG. 3, the air flows from the left side of the blades 132 to the right side of the blades 132. Although a single fan 130 is shown, it is contemplated the micro device 150 may include two or more fans.

During operation, the cooling fan 130 may produce noise, which is also referred to as unwanted sound. The noise may come from friction between the fan components, from friction between the blades and the air, and from air movement. As the load on the fan 130 increases, the fan noise also increases. Because some micro devices may have noise intensity limitations, operation of the cooling fan 130 may be restrained in order to control the fan noise.

FIG. 3 is a diagram of an exemplary noise reduction system 300 suitable for use as the noise reduction system 160 of the micro device 150 shown in FIG. 1, according to some embodiments. The noise reduction system 300 is configured to reduce and/or mask the noise from the cooling fan 130 during operation, thereby allowing the output of the fan 130 to be increased. In one embodiment, the noise reduction system 300 produces a masking sound to reduce the fan noise. In addition to the fan 13, the noise reduction system 300 may be used to reduce noise from other noise producing components, such as a liquid cooling component, an immersion liquid cooling component, and an electrical box. In another embodiment, the noise reduction system 300 produces a masking sound to make the fan noise more pleasant and less intrusive.

In FIG. 3, the noise reduction system 300 includes a reference microphone 310, an electronic controller 340, a speaker 320, and optionally, an error microphone 330. In one example, the reference microphone 310 receives the fan noise and sends it to the controller 340. The controller 340 then drives the speaker 320 to radiate the masking sound. Optionally, the error microphone 330 detects a resulting sound, which may be a combination of the noise and the masking sound, and the controller 340 analyzes the resulting sound and adjusts the masking sound to improve nose reduction performance.

In one embodiment, the reference microphone 310 is configured to sense the noise energy and/or wave amplitude of the noise produced by the fan 130. The microphone 310 may be any suitable acoustic sensor, for example, electrostatic, piezo, and laser microphones. The reference microphone 310 is attached to the housing 108 near the outlet of the fan 130 or positioned at a suitable location for sensing the noise from the fan 130. After sensing the noise, the reference microphone 310 sends the detected noise to the electronic controller 340.

The controller 340 is configured to analyze the noise from the reference microphone 310 and generate a masking sound signal to the speaker 320 to reduce the noise from the fan 130. In one embodiment, the controller 340 is a digital signal processor that controls the speaker 320 to produce the masking sound to reduce the noise, such as by masking the noise. The controller 340 may also include an A/D (analog-to-digital) converter to convert the analog noise from the reference microphone 310 and a D/A (digital-to-analog) converter to convert the masking sound to an analog signal before being output to a speaker. In one example, the controller 340 may determine the sound from the reference microphone 310 is noise, i.e., unwanted sound, and also determine the intensity of the noise.

By detecting the unwanted noise using the reference microphone 310, the noise reduction system 300 can automatically generate the appropriate masking sound signal to send to the speaker 320. In some embodiments, the controller 340 does not generate the masking sound signal unless the detected noise is above a certain intensity threshold value. In one embodiment, the controller 340 selects an appropriate masking sound from a library 342 of masking sounds. In one example, a masking sound is any sound that makes the listener feel happy or relaxed. Characteristics of the masking sound may include constant pitch and a regular periodic motion of sound waves. Exemplary masking sounds include sounds from instruments such as piano, flute, guitar, and violin. One example of masking sound is music, which has a constructed pattern of sound waves. Music may be vocal and/or instrument sounds occurring after one another to create a harmony of sounds. In one example, the masking sound may be music selected from the library 342. Suitable music include classical, jazz, blues, and instrumental. Other exemplary masking sounds include sounds of a river, sounds of birds, sounds of waves, and sounds of rain. The controller 340 may select one or more music to be played by the speaker 320. In one example, the controller 340 may continuously select music to be played, or the controller 340 may play selected music in a loop.

The controller 340 may also determine the intensity of the noise sound received by the reference microphone 310. In response, the controller 340 may control the masking sound to have at least the same or higher intensity. In one example, the intensity of the masking sound is at least one decibel higher than the noise, such as from 1 dB to 10 dB or from 1 dB to 5 dB. In some embodiments, the intensity of the masking sound depends on the size and shape of the housing 108 in which the noise reduction system 300 is applied and the position of the speaker.

The speaker 320 is configured to produce the masking sound to reduce (e.g., mask) the unwanted noise. Suitable speakers include dynamic speaker, Piezo speaker, EMF (Electro-Magnetic Film) speaker or any other type of acoustic transducer. The speaker 320 may be located at or near the location of the noise source, e.g., the fan 130. In one embodiment, the speaker 320 is a Piezo speaker. The speaker 320 is attached to the hub 134 of the fan 130. In another example, the speaker 320 is attached to the interior or the exterior of the housing 108. In another example, the speaker 320 is located where the noise attenuation is desired, for example, a location proximate the housing 108. In another embodiment, the speaker 320 or a plurality of speakers 320 are located in a room where the micro device 150 is located. For example, a plurality of speakers 320 may be positioned at different locations of the room, and the controller 340 may control the plurality of speakers to produce the masking sound.

In some embodiments, the noise reduction system 300 optionally includes an error microphone 330. The error microphone 330 may be located where noise reduction is desired and configured to sense the resulting sound, which maybe a combination of the noise and the masking sound, at its location to monitor the effectiveness of the noise reduction system 300. In one example, the error microphone 330 is located downstream from the reference microphone 310 and the speaker 320. The error microphone 330 may be similar to the reference microphone 310 or any suitable second acoustic sensor. In one embodiment, the controller 340 may analyze the resulting sound from the error microphone 330 and determine whether adjustment is needed to the output of the speaker 320. For example, the controller 340 may determine the intensity of the masking sound may need to be increased to further reduce the fan noise heard in the surrounding environment. In response, the controller 340 may increase the loudness of the masking sound by at least one decibel, such as from 1 dB to 10 dB.

In another embodiment, the controller 340 may optionally send an anti-noise signal to at least partially cancel the noise. In one example, the controller 340 may determine the phase and amplitude of the wave pattern of the noise received by the reference microphone 310. In turn, the controller 340 produces sound waves that are 180 degrees out of phase with the wave pattern of the noise. When summed with the noise, the produced sound waves may cancel out at least a portion of the noise, thereby reducing the intensity of the noise. Because the noise will be at a lower decibel, the intensity of the masking sound may be lowered.

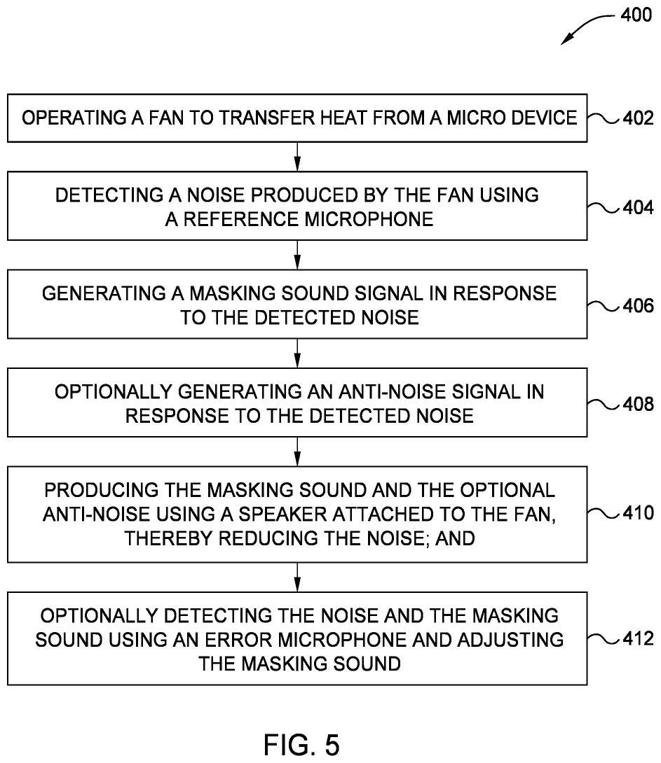

FIG. 5 is a flow diagram of a method 400 for reducing noise from a micro device 150 by producing a masking sound. The method 400 begins at operation 402 where a fan of the micro device is operated to transfer heat from the micro device.

At operation 404, a reference microphone 310 senses a noise produced by the fan 130 of the micro device 150. The reference microphone 310 transmits the detected noise to the controller 340.

At operation 406, the controller 340 analyzes the detected noise and generate a masking sound signal that is sent to the speaker 320. For example, in response to the detected noise, the controller 340 may select music from its library of sound to be sent to the speaker 320. In addition, the controller 340 may control the speaker 320 to play the music at a higher intensity than the noise. In one example, the controller 340 may select one or more classical music to be play at a sound level that is at least 1 dB, such as 2 dB or from 1 dB to 10 dB, higher than the noise.

At operation, 408, the controller 340 may optionally generate an anti-noise signal that is sent to the speaker 320 in addition to the masking sound. The anti-noise signal may have an inverse wave pattern as the detected noise.

At operation 410, the speaker 320 receives the masking sound signal and the optional anti-noise from the controller 340 and produces please sound and the anti-noise. The speaker 320 may be attached to the fan 130, such as attached to the hub 134 of the fan 130.

At operation 412, an optional error microphone 330 may be employed to sense a resulting sound, which may be a combination of the noise, the masking sound, and optionally, the anti-noise. The detected resulting sound is sent to the controller 340 for analysis. In one example, the controller 340 may determine the noise has not been sufficiently reduced. In response, the controller 340 may adjust the intensity of the masking sound, such as by increasing the sound level of the masking sound. Optionally, the controller 340 may adjust the wave pattern of the anti-noise to improve cancellation of the noise. In this manner, the noise generated from the fan 130 may be reduced, thereby allowing the output of the fan 130 to be increased.

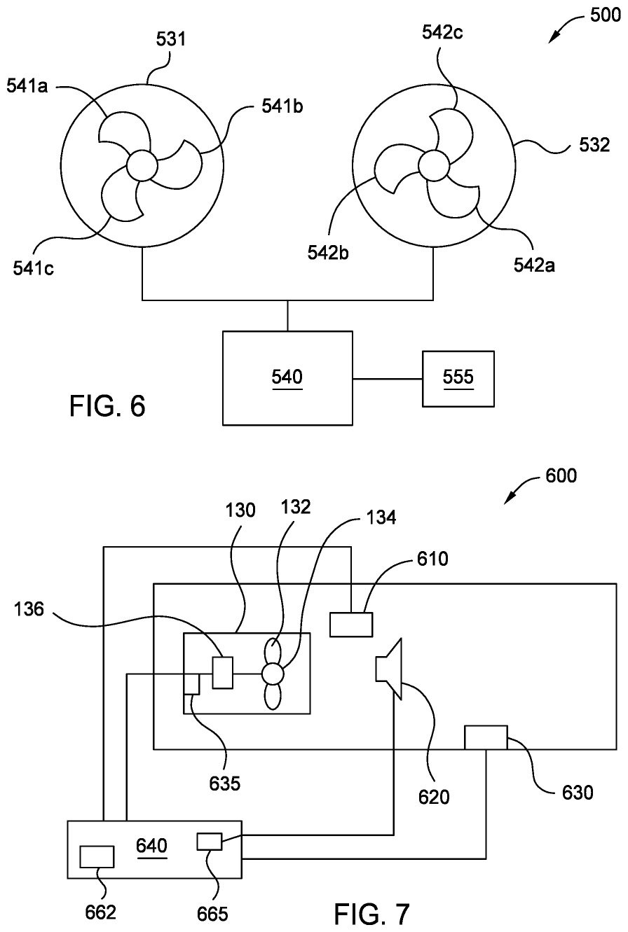

In another embodiment, a noise reduction system 500 is configured to operate a plurality of fans 531, 532 and control the noise from the fans 531, 532. FIG. 6 illustrates an exemplary embodiment of a noise reduction system 500 having two fans 531, 532 connected to a controller 540. Although two fans 531, 532 are shown, the system 500 can include any suitable number of fans, such as three, four, five, six, or more. Each of the fans 531, 532 are provided with three blades 541a-c, 542a-c. The fans 530a-b may be located in a single micro device (e.g., micro device 150) or multiple devices (e.g., multiple servers). In a multiple devices environment, each micro device may have the same or different number of fans. The fans of the same device may be connected to a controller that is connected to a master controller, or the master controller can directly control all of the fans of the multiple devices.

In one embodiment, the fans 531, 532 are configured to operate at the same clock rate, e.g., the same oscillator crystal 555. In this respect, the blades 541a-c, 542a-c of the fans 531, 532 will rotate at the same speed. In one example, the controller 540 may control the rotational position of the blades 541a-c, 542a-c of a fan 531, 532 relative to one or more other fans 531, 532. Referring to FIG. 6, the first blade 541a of the first fan 531 is out of phase (e.g., 180 degrees apart) with the first blade 542a of the second fan 532. For example, the controller 540 may delay the rotation of the second fan 532 relative to the first fan 531, so that their respective blades 541a-c, 542a-c are out of phase with each other. When the blades 541a-c, 542a-c of the fans 531, 532 are out of phase, it is believed the fan noise generated by the first fan 531 will cancel out or reduce the fan noise generated by the second fan 532. In another embodiment, the controller 540 may operate the fans 531, 532 so that their combined fan noise achieves a predetermined noise. For example, the first blades 541a, 542a of the first and second fans 531, 532 are rotated in phase, 30 degrees apart, 45 degrees apart, 60 degrees apart, or the suitable angles. The combined noise of the fans 531, 532 is effective in reducing the fan noise of another device or devices located in the proximity of the fans 531, 532. In another embodiment, the fans 531, 532 operate on different clock rates. The controller 540 can manage of the different clocks to manipulate the noise generated by the fans 531, 532. In another example, the combined noise is more easily masked by the masking sound produced by the noise reduction system 300.

In some embodiments, the micro device 150 may include an audio system 600 for generating a verbal warning message and broadcasting the verbal warning message using a speaker. In one example, an exemplary audio system 600 may include a controller 640 and a speaker 620 as shown in FIG. 7. In another example, the controller 340 and the speaker 320 of FIG. 3 may form part of an audio system 600. In this respect, the controller 340 and the speaker 320 can be used as an audio system, a noise reduction system, or both.

In one embodiment, the controller 640 of the audio system 600 may receive a warning signal from a sensor 610 or another controller that has detected a system event that requires the attention of the operator. In turn, the controller 640 may generate a verbal warning message that communicates at least one of a location or a nature of a warning corresponding to the warning signal. The verbal warning message is produced by the speaker 620. The system event may be any event that requires the attention of operator. Verbal warning messages may be generated for system events such as device failure, overheating, server shutdown, software breach, hardware breach, or other events requiring attention. The audio system 600 may include a library 662 of verbal warning messages corresponding to the system event. The verbal warning message communicates at least one of the location of the event or the nature of the event. In this respect, the audio system 600 advantageously provides notification of the occurrence of system events to the operator. If multiple electronic devices are located in the same space, the audio system 600 can easily indicate the particular electronic device experiencing the system event.

In one example, the controller 640 of the audio system 600 may receive a fan noise signal from an acoustic sensor 610 (e.g., reference microphone) that is above a predetermined a certain threshold sound level. In response, the controller 640 may generate a verbal warning message 665 such as “fan noise too loud.” If more than one fan is present, the verbal warning message 665 may also identify the fan, for example, “fan number two.” The verbal warning message 665 is then produced by the speaker 620. In one example, the verbal warning message 665 may repeat until a response is received, such as from the operator. In some embodiments, the audio system 600 can broadcast a masking sound when the noise is below the predetermined sound level. The audio system 600 may continue to broadcast the masking sound until the sound level reaches or is above the predetermined sound level threshold. At which time, the audio system 600 will generate and broadcast the verbal warning message.

In another example, the controller 640 of the audio system 600 may receive a signal from a sensor 635 monitoring the temperature of the motor 136 of the fan 130 or other devices. When the temperature reaches a predetermined temperature, the controller 640 may generate a verbal warning message 665 such as “fan motor is overheating.” In another example, the sensor 635 may be configured to monitor the rotation of the blades 132 of the fan 130. If the blades 132 slow down or rotate erratically, the controller 640 may generate a verbal warning message 665 such as “fan blade error.” The verbal warning message 665 is sent to and produced by the speaker 620. In one example, the verbal warning message 665 may repeat until a response is received, such as from the operator.

In another example, the controller 640 of the audio system 600 may receive a signal from a sensor 635 monitoring the temperature of the motor 136 of the fan 130 or other devices. When the temperature reaches a predetermined temperature, the controller 640 may generate a verbal warning message 665 such as “fan motor is overheating.” In another example, the sensor 635 may be configured to monitor the operation of the blades 132 of the fan 130. The noise signal may be examined for noise generated by the bearing to predict the maintenance requirement or potential failure of the fan 130. If the blades 132 slow down or rotate erratically, the controller 640 may generate a verbal warning message 665 such as “fan blade error” “fan maintenance required.” The verbal warning message 665 is sent to and produced by the speaker 620. In one example, the verbal warning message 665 may repeat until a response is received, such as from the operator.

In another example, the controller 640 of the audio system 600 may receive a signal regarding a security breach of the system. For example, a sensor 630 may identify a hardware breach upon the insertion of an unauthorized foreign device, such as a USB device. The controller 640 may generate a verbal warning message 665 such as “hardware breach.” The verbal warning message 665 may also identify location of the port and/or the PCB board of the breach. In some embodiments, the controller 640 may receive a signal regarding a software breach and generate a corresponding verbal warning message 665. In one example, the controller 640 may receive a signal from a sensor for detecting a backside attack of an IC chip, such as an attach using an optical probe. The controller 640 may generate a verbal warning message to notify the backside attack.

In one example, a micro device includes a housing; a chip package disposed in the housing; a noise producing component coupled to the housing. The micro device also includes a noise reduction system having a reference microphone for detecting a noise from the noise producing component and a controller configured to receive the noise from the reference microphone and generate a masking sound signal in response to the detected noise. A speaker is coupled to the housing for producing a masking sound corresponding to the masking sound signal, whereby the masking sound reduces the noise.

In one example, a micro device includes a housing; a chip package disposed in the housing; and a fan coupled to the housing. The micro device also includes a noise reduction system having a reference microphone for detecting a noise produced by the fan. A controller receives the noise from the reference microphone and generate a masking sound signal in response to the detected noise. A speaker attached to the fan produces a masking sound corresponding to the masking sound signal, whereby the masking sound reduces the noise.

In another example, the noise producing component comprises a fan.

In another example, an electronic device includes a housing, a chip package disposed in the housing, and a plurality of fans coupled to the housing. A fan controller controls a fan noise by controlling a rotational position of a blade of a first fan of the plurality of fans relative to a rotational position of a blade of a second fan of the plurality of fans.

In another example, an electronic system includes a housing, a printed circuit board disposed in the housing, and a chip package connected to the printed circuit board. The electronic system also includes an audio system having a controller configured to receive a warning signal and to generate a verbal warning message which communicates at least one of a location or a nature of a warning corresponding to the warning signal and a speaker for producing the verbal warning message.

In another example, a method of operating a micro device includes operating a fan to transfer heat away from the micro device. The method also includes detecting a noise produced by the fan using a reference microphone. A masking sound signal is generated in response to the detected noise. A speaker attached to the fan produces a masking sound corresponding to the masking sound signal, thereby reducing the noise from the fan.

In another example, the method includes generating an anti-noise signal configured to at least partially cancel the noise.

In another example, the method includes detecting the noise and the masking sound using an error microphone.

In another example, the method includes adjusting the masking sound in response to the masking sound detected by the error microphone by increasing its sound intensity.

In another example, the method includes adjusting the anti-noise.

In another example, producing the masking sound comprises producing the masking sound at a higher intensity than the noise.

In another example, the method includes the masking sound signal is selected from a library of masking sound signals.

While the foregoing is directed to embodiments of the present invention, other and further embodiments of the invention may be devised without departing from the basic scope thereof, and the scope thereof is determined by the claims that follow.

What is claimed is:

1. A micro device, comprising:
a housing;
a chip package disposed in the housing;
a noise producing component coupled to the housing; and
a noise reduction system, having:
a reference microphone for detecting a noise from the noise producing component;
a controller configured to receive the noise from the reference microphone and generate a masking sound signal in response to the noise; and
a speaker coupled to the housing for producing a masking sound corresponding to the masking sound signal, whereby the masking sound reduces the noise.

2. The micro device of claim 1, wherein the reference microphone is attached to the housing.

3. The micro device of claim 1, further comprising an error microphone for detecting the noise and the masking sound.

4. The micro device of claim 3, wherein the controller is configured to adjust the masking sound signal in response to the noise and the masking sound detected by the error microphone.

5. The micro device of claim 1, wherein the speaker is attached to one of the housing or the noise producing component.

6. The micro device of claim 1, wherein the speaker comprises a piezo speaker.

7. The micro device of claim 1, wherein the masking sound has a higher intensity than the noise from the noise producing component.

8. The micro device of claim 1, further comprising a library of masking sounds.

9. The micro device of claim 8, wherein the masking sound comprises music.

10. The micro device of claim 9, wherein when the noise reaches a predetermined sound level, the controller generates a verbal warning message identifying an excessive sound level.

11. The micro device of claim 1, wherein the controller is further configured to receive a warning signal and to generate a verbal warning message which communicates at least one of a location or a nature of a warning corresponding to the warning signal, and the speaker produces the verbal warning message.

12. The micro device of claim 1, wherein the noise producing component comprises a fan.

13. An electronic device, comprising:
a housing;
a chip package disposed in the housing;
a plurality of fans coupled to the housing; and
a fan controller configured to control a fan noise by controlling a rotational position of a blade of a first fan of the plurality of fans relative to a rotational position of a blade of a second fan of the plurality of fans.

14. The electronic device of claim 13, wherein the plurality of fans are synchronized to a same clock signal.

15. The electronic device of claim 13, wherein the rotational position of the blade of the first fan is out of phase relative to the rotational position of the blade of the second fan.

16. The electronic device of claim 13, wherein the rotational positions of the blades of the first fan and the second fan are controlled to produce a predetermined fan noise.

17. The electronic device of claim 13, further comprising:
a noise reduction system configured to produce a masking sound in response to the fan noise.

18. An electronic system, comprising:
a housing;
a printed circuit board disposed in the housing;
a chip package connected to the printed circuit board;
an audio system, having:
a controller configured to receive a warning signal and to generate a verbal warning message which communicates at least one of a location or a nature of a warning corresponding to the warning signal; and
a speaker for producing the verbal warning message.

19. The electronic system of claim 18, further comprising:
a reference microphone for detecting a noise produced by a fan disposed in the housing;
the controller configured to receive the noise from the reference microphone and generate a masking sound signal in response to the noise; and
the speaker producing a masking sound corresponding to the masking sound signal, whereby the masking sound reduces the noise.

20. The electronic system of claim 18, wherein the nature of the warning is one of a component failure, overheating, hardware breach, or software breach.
